(19) United States
(12) Patent Application Publication
(10) Pub. No.: US 2026/0173899 A1
(43) Pub. Date: Jun. 18, 2026

(54) ULTRA-LOW INDUCTANCE FAST SWITCHING PACKAGING DESIGN FOR WIDE BANDGAP POWER MODULES

(71) Applicant: Alliance for Energy Innovation, LLC, Golden, CO (US)

(72) Inventors: Shuofeng ZHAO, Lakewood, CO (US); Joshua John MAJOR, Kittredge, CO (US); MD Sarwar ISLAM, Lakewood, CO (US); Douglas John DEVOTO, Nederland, CO (US); Faisal Habib KHAN, Littleton, CO (US)

(21) Appl. No.: 19/420,570

(22) Filed: Dec. 15, 2025

Related U.S. Application Data
(60) Provisional application No. 63/733,646, filed on Dec. 13, 2024.

(51) Int. Cl. H10W 70/40; H10D 80/20; H10W 90/00

(52) U.S. Cl. CPC H10W 70/451; H10D 80/251; H10W 70/429; H10W 70/461; H10W 70/481; H10W 90/811

(57) ABSTRACT

The present disclosure relates to a device that includes a plurality of electrically conductive layers, a plurality of dielectric layers, and at least two recesses positioned in at least one electrically conductive layer, each recess configured to receive an electronic element. Further, the electrically conductive layers are positioned parallel to a reference plane, the dielectric layers are positioned parallel to the reference plane, and the electrically conductive layers and the dielectric layers are positioned to form a stack that is aligned symmetrically in the direction of a reference axis that is perpendicular to the reference plane and in a substantially circular arrangement around the reference axis.

### CROSS-REFERENCE TO RELATED APPLICATIONS

This application claims the benefit of U.S. Provisional Application No. 63/733,646 filed Dec. 13, 2024, the contents of which are incorporated herein by reference in their entirety.

### CONTRACTUAL ORIGIN

This invention was made with government support under Contract No. DE-AC36-08GO28308 awarded by the Department of Energy. The government has certain rights in this invention.

### BACKGROUND

Conventional high-power, hundreds of kilowatt-level traction inverters, grid-tied inverters, and DC-to-DC converters are heavy and bulky, inducing high cost in construction, installation, and maintenance. Thus, there remains a need for smaller and lighter converters to reduce costs and increase flexibility in power conversion applications.

### SUMMARY

An aspect of the present disclosure is a device that includes a plurality of electrically conductive layers, a plurality of dielectric layers, and at least two recesses positioned in at least one electrically conductive layer, each recess configured to receive an electronic element. Further, the electrically conductive layers are positioned parallel to a reference plane, the dielectric layers are positioned parallel to the reference plane, and the electrically conductive layers and the dielectric layers are positioned to form a stack that is aligned symmetrically in the direction of a reference axis that is perpendicular to the reference plane and in a substantially circular arrangement around the reference axis. In some embodiments of the present disclosure, the device may be configured to transfer electricity to the electronic elements and transfer heat away from electronic elements positioned in recesses.

In some embodiments of the present disclosure, the electrically conductive layers may include a multi-lobed structure having a central hub having a center positioned at the reference axis and at least four lobes, each physically connected to the central hub and positioned radially around the reference axis. Further, the lobes may form spaces, e.g., at least four spaces, with each space positioned between two adjacent lobes and positioned around the reference axis, and at least one lobe may have at least one of the at least two recesses.

In some embodiments of the present disclosure, the electrically conductive layers may further include at least four single-lobed structures, where each single-lobed structure includes a lobe and a tab protruding from the lobe at an angle perpendicular to the lobe and aligned perpendicular to the reference axis. Further, at least one lobe may include at least one of the at least two recesses. In some embodiments of the present disclosure, each lobe of a single-lobed structure may be positioned within one of the spaces positioned between adjacent lobes of the multi-lobed structure. In some embodiments of the present disclosure, the multi-lobed structure and the lobe of each single-lobed structure may be positioned within a single plane that is parallel to the reference plane.

In some embodiments of the present disclosure, the electrically conductive components may further include an alignment structure comprising at least four notches and at least four slots, where each notch is configured to receive and align the tab of one of the single-lobed structures, and each slot is positioned between two notches.

In some embodiments of the present disclosure, a device may further include a first dielectric layer, where the first dielectric layer has a shape substantially similar to the alignment structure and comprises at least four notches and at least four slots, the first dielectric layer is positioned between the alignment structure and the single-lobed structures, and each notch of the first dielectric layer is configured to receive the tab of a single-lobed structure.

In some embodiments of the present disclosure, a device may further include at least four planar tabs positioned perpendicularly to the reference plane, where each planar tab passes through a slot of the alignment structure and a slot of the first dielectric layer. In some embodiments of the present disclosure, a device may further include at least four flanged planar tabs positioned perpendicularly to the reference plane, where each flanged planar tab is positioned parallel to and adjacent to one of the planar tabs. In some embodiments of the present disclosure, there may be a gap between the flanged planar tab and the planar tab.

In some embodiments of the present disclosure, the electrically conductive layers may further include a first conductive bridge having at least four notches, each configured to receive a tab of a single-lobed structure, with the first conductive bridge electrically connected to the alignment structure.

In some embodiments of the present disclosure, a device may further include a second dielectric layer, where the second dielectric layer has a shape substantially similar to the first conductive bridge and comprises at least four notches, the first conductive bridge is positioned between the second dielectric layer and the alignment structure, and each notch of the second dielectric layer is configured to receive and align the tab of one of the single-lobed structures.

In some embodiments of the present disclosure, the electrically conductive layers may further include a second conductive bridge, with the second dielectric layer positioned between the second conductive bridge and the first conductive bridge.

An aspect of the present disclosure is method for manufacturing a device, where the method includes aligning and bonding electrically conductive layers and dielectric layers to form a stack.

### BRIEF DESCRIPTION OF THE DRAWINGS

Some embodiments of the present disclosure are illustrated in the referenced figures of the drawings. It is intended that the embodiments and figures disclosed herein are to be considered illustrative rather than limiting.

FIG. 1 illustrates a circuit diagram for an inductance half-bridge (HB) device that includes multiple metal-oxide-semiconductor field-effect transistors (MOSFETs), according to some aspects of the present disclosure.

FIG. 2 illustrates various views of an inductance half-bridge (HB) device, according to some aspects of the present disclosure.

FIG. 3 illustrates an exploded view of the device illustrated in FIG. 2, according to some aspects of the present disclosure.

FIG. 4 illustrates an example of a multi-lobed structure (Panel A) and a single-lobed structure (Panel B), according to some aspects of the present disclosure.

FIG. 5 illustrates a method for making the device illustrated in FIG. 1 and FIG. 2, according to some aspects of the present disclosure.

FIG. 6 illustrates (left) an exploded view of an exemplary SiC MOSFET HB module, (upper right) photographs of the exemplary SiC MOSFET HB module, and (lower right) shows the exemplary SiC MOSFET HB module being tested, according to some aspects of the present disclosure.

FIGS. 7A-7F illustrate experimental evaluation of the switching transient performance of the exemplary SiC MOSFET HB module, according to some aspects of the present disclosure. FIG. 7A illustrates 50 kHz switching waveform overview, zero load with no output inductor connected, FIG. 7B illustrates 50 kHz switching wave-form overview, 10A load current, FIG. 7C illustrates high-side switch turn-on transient under zero load with no output inductor connected, FIG. 7D illustrates high-side switch turn-off transient under zero load with no output inductor connected, FIG. 7E illustrates high-side switch turn-on transient under 10A load current, and FIG. 7F illustrates high-side switch turn-off transient under 10A load current.

FIGS. 8A-8F illustrate corresponding simulation results of the switching transients of the exemplary SiC MOSFET HB module, according to some aspects of the present disclosure. FIG. 8A illustrates 50 kHz switching waveform overview, zero load with no output inductor connected, FIG. 8B illustrates 50 kHz switching waveform overview, 10A load current, FIG. 8C illustrates high-side switch turn-on transient under zero load with no output inductor connected, FIG. 8D illustrates high-side switch turn-off transient under zero load with no output inductor connected, FIG. 8E illustrates high-side switch turn-on transient under 10A load current, and FIG. 8F illustrates high-side switch turn off transient under 10A load current.

### REFERENCE NUMERALS

100 . . . circuit
110 . . . electronic elements
200 . . . device
205 . . . baseplate
207 . . . third dielectric layer
215 . . . multi-lobed structure
216 . . . central hub
217 . . . lobe
218 . . . space
219 . . . recess
244 . . . single-lobed structure
245 . . . tab
265 . . . first dielectric layer
260 . . . alignment structure
270 . . . planar tabs
275 . . . flanged planar tabs
280 . . . first conductive bridge
285 . . . second dielectric layer
290 . . . second conductive bridge
400 . . . method
410 . . . first bonding
415 . . . first pre-bonding
420 . . . first aligning
425 . . . second bonding
430 . . . second aligning
435 . . . second pre-bonding
440 . . . third aligning
445 . . . fourth aligning
450 . . . third bonding
455 . . . high electric potential testing
460 . . . fifth aligning
465 . . . sixth aligning
470 . . . seventh aligning
475 . . . eighth aligning
480 . . . soldering
485 . . . attaching

### DETAILED DESCRIPTION

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

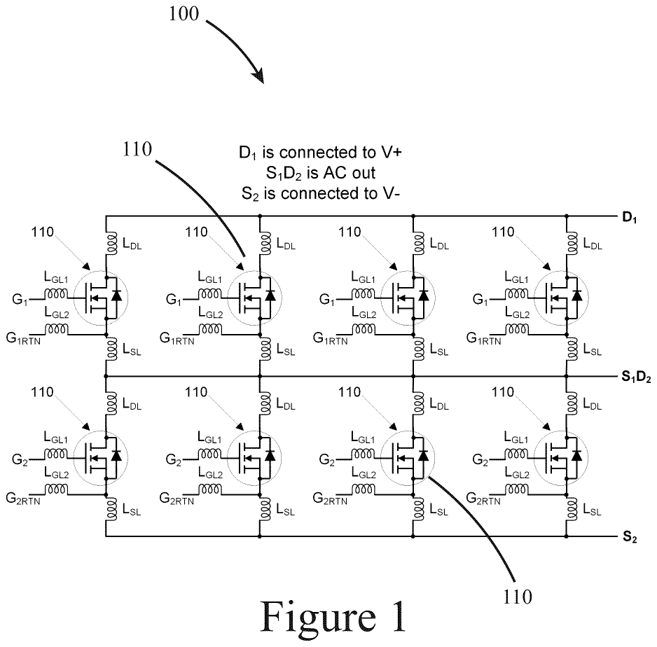

FIG. 1 illustrates a circuit diagram of a half-bridge (HB) module, according to some embodiments of the present disclosure. In this exemplary HB, there is one upper position switch and a lower position switch. In normal operations, the upper and lower switches will turn on or off complementarily to create high and low voltage levels at the midpoint (SID2). In this example, both the upper and lower switch have four electronic elements 110 in parallel. However, the number of electronic elements in each position is arbitrary depending on current capacity demand as long as there are equal number of elements in upper and lower positions.

Among other things, the present disclosure relates to a sub-nanohenry ultra-low inductance half-bridge (HB) layout design with symmetrical current paths powered by organic direct bonded copper (ODBC) packaging technology which enables a flexible three-dimensional (3D) layout. A high degree of magnetic flux cancellation may be achieved, resulting in extremely low loop inductance. Low inductance allows extremely high current change rate (di/dt) and, as a result, very short turn-on and turn-off times. Combined with the inherent fast switching capability of wide bandgap (WBG) semiconductor devices such as silicon carbide (SiC) and gallium nitride (GaN), the design of this present disclosure may achieve very high-power densities at up to 1.2 kV voltage rating. The symmetrical layout may allow easy scalability of current capacity up to kA level. This design of the present disclosure is also fabrication-friendly with mostly non-exotic components and a relatively simple fabrication process. HB power modules are the primary building block for power converters widely used in electric vehicles (EV) and other clean energy power conversion applications. The fast-switching HB design of the present disclosure contributes directly to low power loss and a smaller footprint of passive components such as inductors and capacitors in power converters, leading to low volume, lightweight, and high efficiency. These are all highly valued properties.

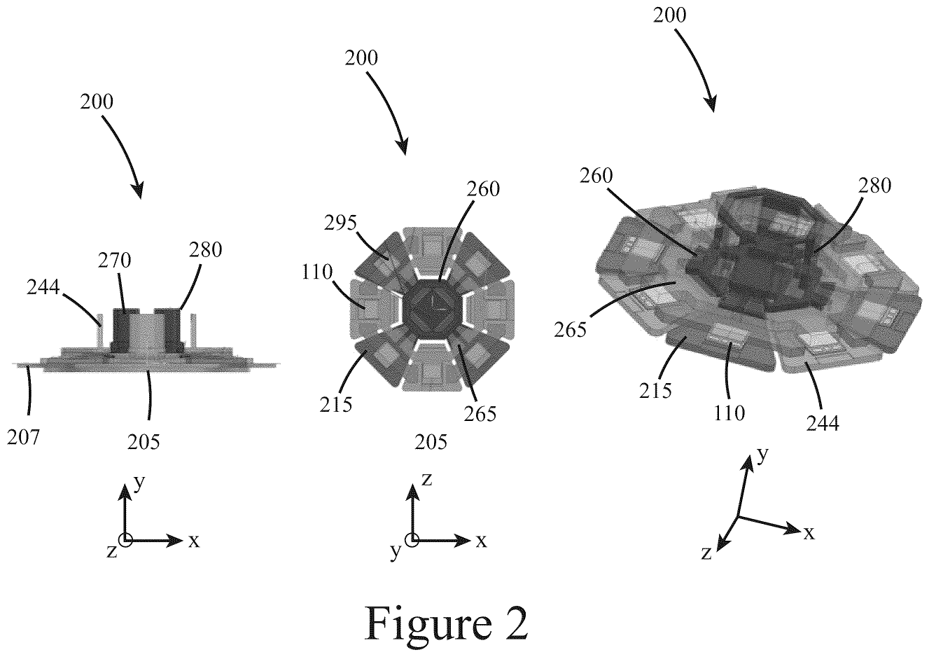

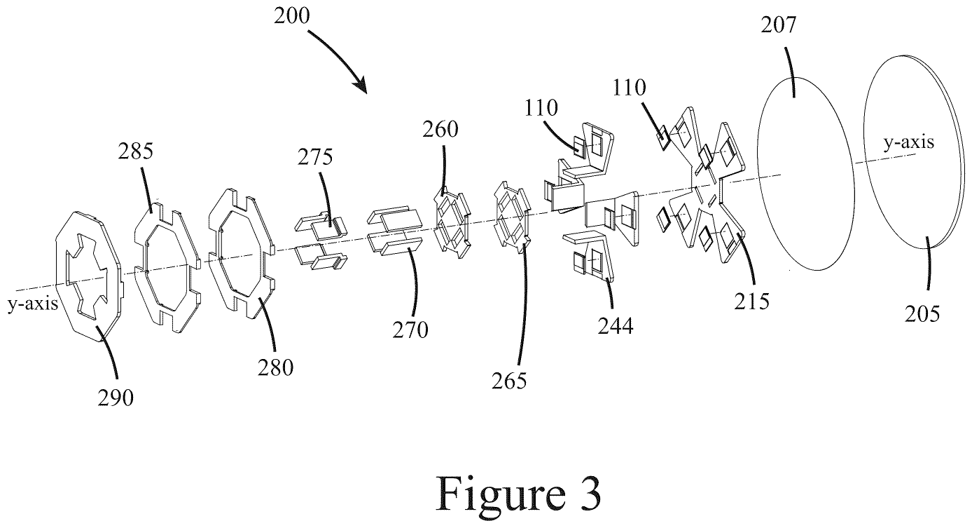

FIG. 2 and FIG. 3 illustrate an exemplary silicon carbide (SiC) metal oxide field effect transistor (MOSFET) half-bridge (HB) module, referred to herein as a “device”, according to some aspects of the present disclosure. In this embodiment, a DC+ contact and mid-point bus bars may be used as a primary thermal conduction path. Heat loss may be transferred through these bus bars and a dielectric layer to reach an underlying metallic (e.g., copper) baseplate. A DC− bus bar may have a compact and symmetrical footprint and may be bonded to the top surface of the DC+ bus bar with another layer of dielectric material to allow reduced current loop area and symmetrical current paths and also provide moderate DC capacitance. Four pairs of bonded bridges (i.e., metal conductors), connecting the high-side source to the mid-point and the low-side source to a DC− contact from each electronic element (e.g., MOSFET chip) to its adjacent die position respectively, making relatively compact and substantially symmetrical current paths.

Table 1 summarizes nomenclature, reference numerals, and descriptions of the key elements described herein that are used to construct the devices described herein, according to some embodiments of the present disclosure.

TABLE 1
Device Elements

| # | Name | Description |
|---|---|---|
| 207 | Polyimide | Organic insulator that blocks electrical contact and |
| | dielectric film | conducts heat flux |
| 205 | Copper | Conductive metal plate for structural support and heat |
| | baseplate | extraction |
| 215 | DC+ bus bar | A piece of metal for current path for the DC+ node (like |
| | (same piece as | a cathode) |
| | 120 and 125) | |
| 230 | High | A buffer for evenly distributing pressure during the final |
| | temperature | bonding of the piece of polyimide between DC+ and DC− |
| | rubber | bus bars. This rubber is for bonding the bottom surface of |
| | | the polyimide with the top surface of the DC+ bus bar |
| 265 | Dielectric | The piece of polyimide between DC+ and DC− bus bars |
| | Isolation | |
| | between DC+ | |
| | and DC− bus | |
| | bars | |
| 240 | Aligning | An SLA 3D printed and solidified resin block which has |
| | fixture for | alignment holes and impressions that hold DC+, DC−, |
| | holding DC+, | and four separate AC bus bars in place. It's used for pre- |
| | DC−, and four | bonding the four AC bus bars to the top surface of 105. |
| | separate AC bus | |
| | bars in place | |
| 242 | High | A buffer for evenly distributing pressure during the final |
| | temperature | bonding of the piece of the four AC bus bars onto the top |
| | rubber | surface of 105 |
| 244 | (One of four | A piece of metal for current path for the AC, or mid-point |
| | separate) AC | node of the half-bridge module |
| | bus bars | |
| 245 | High | Another layer of buffer for evenly distributing pressure |
| | temperature | during the final bonding of all four AC bus bars onto the |
| | rubber | top surface of 105 |
| 250 | Steel pressing | A set of steel spacers used to exert force onto all four |
| | tool | pieces of 144 for the final bonding of all four AC bus |
| | | bars onto the top surface of 105 |
| 260 | DC− bus bar | A piece of metal for current path for the DC− node (like |
| | | an anode) |
| 265 | Polyimide | Dielectric isolation between the DC+ bus bar |
| | dielectric film | (115/120/125) and DC− bus bar (160) |
| 110 | | MOSFET chips, eight in total, four upper and four lower |
| | | (which are in place after the alignment fixture is |
| | | removed). |
| | | Please note that the exact number of chips are scalable |
| | | depending on the current capacity demand, as long as |
| | | they are in even numbers (the same number in the upper |
| | | and lower position) and the symmetry is preserved. |
| 270 | DC+ Current | Vertical conductors to be attached to the DC+ bus bars |
| | terminals | for external access |
| 275 | DC− Current | Vertical conductors to be attached to the DC− bus bars for |
| | terminals | external access |
| 280 | Upper position | Conductor bridges connecting the top surfaces of lower |
| | conductor | position half bridge chips and DC− bus bar |
| | bridge | |
| 290 | Lower position | Conductor bridges connecting the top surfaces of upper |
| | conductor | position half bridge chips and four 144 |
| | bridge | |
| 285 | Polyimide | Dielectric isolation between the upper conductor bridge |
| | dielectric film | (180) and lower conductor bridge (185) |

FIGS. 2 and 3 illustrate a device 200, according to some embodiments of the present disclosure. As described herein, the exemplary device 200 includes a stack formed from a plurality of electrically conductive layers and a plurality of dielectric layers, where at least one electrically conductive layer is shaped to include a recess 219 configured to receive an electronic element 110, for example a MOSFET chip. Referring to FIG. 2, both the electrically conductive layers and the dielectric layers are positioned parallel to a reference plane (the xz-plane). Unique to the design of the devices 200 described herein, the electrically conductive layers and the dielectric layers are positioned to form a stack that is aligned symmetrically in the direction of a reference axis (the y-axis) that is perpendicular to the reference plane and in a substantially circular arrangement around the reference axis (the y-axis). Among other things, this symmetrical, circular arrangement enables the device 200 to effectively transfer electricity to the electronic elements 110 and transfer heat away from electronic elements 110 positioned in recesses 219.

The electrically conductive layers, being conductive, may be characterized by being fabricated from materials having an electrical conductivity between 1×10⁶ S/m and 100×10⁶ S/m, for example a metal. In some embodiments of the present disclosure, a metal used to fabricate an electrically conductive layer may include at least one of copper, aluminum, silver, gold, nickel, steel, molybdenum, or a combination thereof.

Similarly, the dielectric layers being electrically insulating may be characterized by being fabricated from materials having an electrical conductivity between 1×10⁻¹⁷ S/m and 1×10⁻¹⁰ S/m, for example, a polymer, a resin, or a combination thereof. In some embodiments of the present disclosure, a polymer or resin used to construct a dielectric layer may have a dielectric strength between 4 kV and 6.5 kV. In some embodiments of the present disclosure, a polymer or resin used to construct a dielectric layer may have a thermal conductivity between 0.2 W/[m·K] and 0.7 W/[m·K]. In some embodiments of the present disclosure, the polymer or resin used to construct a dielectric layer may include at least one of a polyimide, a polyetherimide (PEI), a polyetheretherketone (PEEK), polytetrafluoroethylene (PTFE), polyethylene terephthalate (PET), polyethylene naphthalate (PEN), an epoxy resin, or a combination thereof. In some embodiments of the present disclosure, a polymer or resin may be capable of being cut using a CO₂ laser cutter.

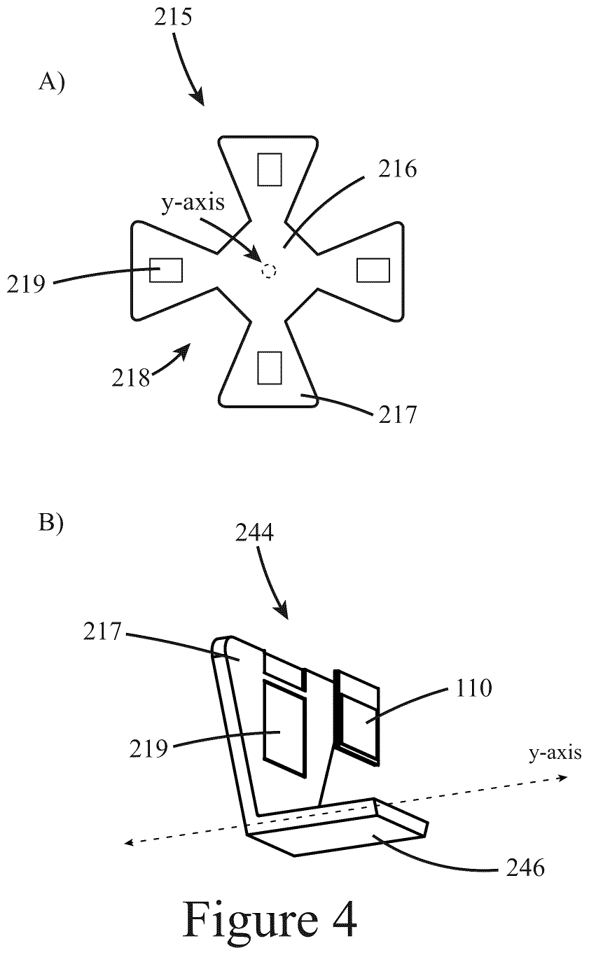

As shown herein, referring to FIG. 3 and FIG. 4, the electrically conductive layers may include a multi-lobed structure 215 having a central hub 216 having a center positioned at the reference axis, to which are connected at least four lobes 217, each positioned radially around the reference axis. Further, the location of the lobes 217 forms at least four spaces 218, with each space 218 positioned between two adjacent lobes 217 and positioned around the reference axis. Further, at least one lobe 217 of the multi-lobed structure 215 is formed to include at least one of the at least two recesses 219 configured to receive the electronic element 110. As described herein, a multi-lobed structure 215 may be configured to function as a DC+ contact (i.e., DC+ node). In some embodiments of the present disclosure, each lobe 217 may have a polygonal shape.

Referring again to FIG. 3 and FIG. 4, the electrically conductive layers of the device 200 may further include at least four single-lobed structures 244, where each single-lobed structure 244 has a lobe 217 and a tab 245 protruding from the lobe 217 at an angle perpendicular to the lobe 217 and aligned perpendicular to the reference axis, and at least one lobe 217 is shaped to include at least one of the at least two recesses 219 configured to receive the electronic element 110. As described herein, single-lobed structures 244 may be configured to function as an AC contact (i.e., AC node). Referring to FIG. 2, each lobe 217 of a single-lobed structure 244 may be positioned within one of the spaces 218 positioned between adjacent lobes 217 of the multi-lobed structure 215. In some embodiments of the present disclosure, the multi-lobed structure 215 and the lobe 217 of each single-lobed structure 244 may be positioned within a single plane that is parallel to the reference plane.

In some embodiments of the present disclosure, the electrically conductive components of the device 200 may further include an alignment structure having at least four notches and at least four slots, where each notch is configured to receive and align the tab 245 of one of the single-lobed structures 244, and each slot is positioned between two notches. As described herein, an alignment structure may be configured to function as a DC− bus bar.

In some embodiments of the present disclosure, a device 200 may include a first dielectric layer, where the first dielectric layer has a shape substantially similar to the alignment structure and includes at least four notches and at least four slots. In some embodiments of the present disclosure, the first dielectric layer may be positioned between the alignment structure and the single-lobed structures 244, and each notch of the first dielectric layer may be configured to receive the tab 245 of a single-lobed structure 244.

In some embodiments of the present disclosure, a device 200 may further include at least four planar tabs 270 positioned perpendicularly to the reference plane, where each planar tab 270 passes through a slot of the alignment structure and a slot of the first dielectric layer. In some embodiments of the present disclosure, each planar tab 270 may be configured to function as DC+ bus bars. In some embodiments of the present disclosure, a device 200 may further include at least four flanged planar tabs 275 positioned perpendicularly to the reference plane, where each flanged planar tab 275 is positioned parallel to and adjacent to one of the planar tabs 270. In some embodiments of the present disclosure, there may be a gap between the flanged planar tab 275 and the planar tab 270. As described herein, flanged planar tabs 275 may be configured to function as DC− bus bars.

In some embodiments of the present disclosure, the electrically conductive layers of the device 200 may further include a first conductive bridge 280 having at least four notches, where each configured to receive a tab 245 of a single-lobed structure 244, and the first conductive bridge 280 is electrically connected to the alignment structure. In some embodiments of the present disclosure, a first conductive bridge 280 may be configured to function as an electrical contact between the electronic elements 110 and the alignment structure.

In some embodiments of the present disclosure, a device 200 may further include a second dielectric layer 285, where the second dielectric layer 285 has a shape substantially similar to the first conductive bridge 280 and has at least four notches, the first conductive bridge 280 is positioned between the second dielectric layer 285 and the alignment structure, and each notch of the second dielectric layer 285 is configured to receive and align the tab 245 of one of the single-lobed structures 244.

In some embodiments of the present disclosure, the electrically conductive layers may further comprise a second conductive bridge 290, where the second dielectric layer 285 is positioned between the second conductive bridge 290 and the first conductive bridge 280. In some embodiments of the present disclosure, a second conductive bridge 290 may be configured to function as an electrical contact between the electronic elements 110 and the single-lobed structures 244. In some embodiments of the present disclosure, a device 200 may further include a third dielectric layer 207, and the electrically conductive layers further include a baseplate 205, where the third dielectric layer 207 is positioned between the multi-lobed structure 215 and the baseplate 205.

In some embodiments of the present disclosure, the device 200 may be configured to operate as a half-bridge power module. In some embodiments of the present disclosure, the plurality of electronic elements 110 may include metal-oxide-semiconductor field-effect transistors (MOSFETs).

In some embodiments of the present disclosure, the multi-lobed structure 215 may have between 4 and 20 lobes, or between 4 and 10 lobes. In some embodiments of the present disclosure, a multi-lobed structure 215 has four lobes. In some embodiments of the present disclosure, each lobe of a multi-lobed structure 215 may have between 1 and 10 recesses 219, or between 1 and 4 recesses 219. In some embodiments of the present disclosure, each lobe of a multi-lobed structure 215 may have a single recess 219.

In some embodiments of the present disclosure, a device 200 may have between 4 and 20 single-lobed structures 244, or between 4 and 10 single-lobed structures 244. In some embodiments of the present disclosure, a device 200 has four single-lobed structures 244. In some embodiments of the present disclosure, each lobe of each single-lobed structure 244 may have between 1 and 10 recesses 219, or between 1 and 4 recesses 219. In some embodiments of the present disclosure, each lobe of each single-lobed structure 244 has a single recess 219.

In some embodiments of the present disclosure, the method of fabricating and designing a device 200 (e.g., a SiC MOSFET HB module) may include the use of a consumer-grade computer numerical control (CNC) milling machine, which may be capable of working conductive metals (e.g., copper) at approximately 0.1 mm precision, to produce the desired features. In some embodiments of the present disclosure, a method for manufacturing a device 200, may include a hot-press, which may be assembled from consumer grade linear stages, stepper motors, and a heating plate (which may achieve temperatures up to and excess of 350° C.), thermal couples and temperature control, pressure sensors, Python programming for controlling temperature and pressure, for bonding the polyimide and copper. These manufacturing features may result in a low-cost, fast, flexible approach manufacturing method. Alternative approaches with the same functionality may also be adopted. For example, methods for manufacturing devices as described herein may include a 3D printer which can print materials at temperatures not less than the hot press temperature and substantially sufficient rigidity to withstand at least 300 psi pressure without major uneven deformation. Some embodiments may also include a consumer grade laser cutter capable of cutting through sheets of dielectric materials (e.g., polyimide) having thicknesses up to approximately 50 μm.

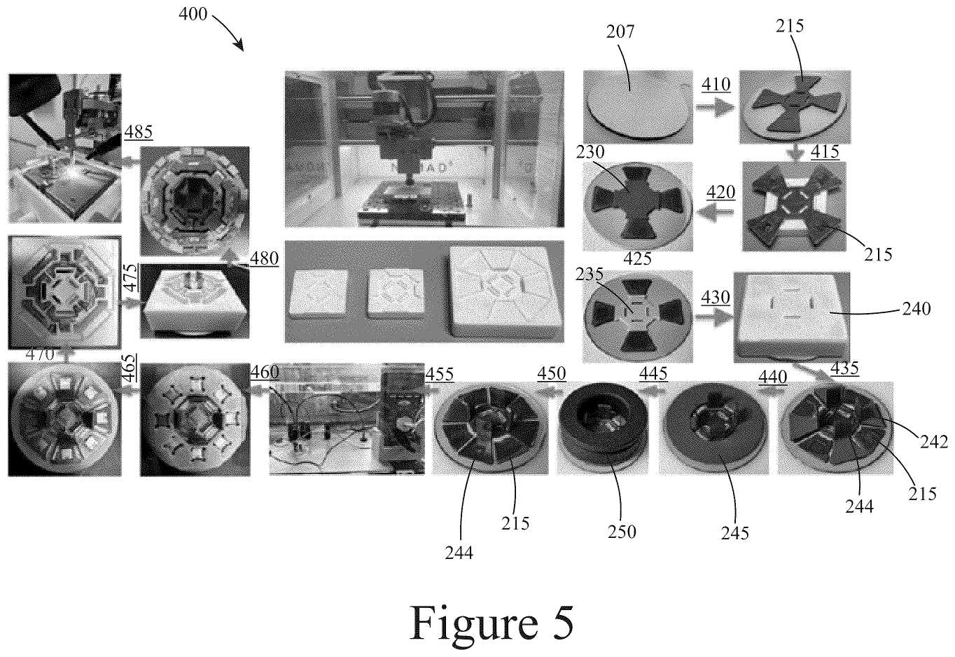

FIG. 5 illustrates a method of designing and fabricating a SiC MOSFET HB module, according to some aspects of the present disclosure. In some embodiments, the method includes machining the copper features of the SiC MOSFET HB module. Next, the method includes cutting the polyimide material using the laser cutter. Next, the method includes 3D-print bonding molds per the footprints of the bonding surface and print soldering mold per the footprints of 3D overlay components. In the examples shown in FIGS. 2, 3, and 6, SLA printing using a highly rigid resin was employed to produce molds with substantially high infill density and substantial homogeneity. Next, the method-proceeded to pre-bonding the polyimide and copper using the bonding molds for substantially reliable alignment purposes. Due to polyimide's tendency to demonstrate very low friction on the metal surface-to-be-bonded, this pre-bonding step enables the subsequent bonding of polyimide and copper components with each in their correct position. Thus, the method continues with the bonding together of the polyimide and copper using the pressing tool and a temporary intervening high-temperature rubber. This rubber layer assists with the even distribution of force across the planar surfaces of the polyimide and copper elements to ensure stable and consistent bonding and electrical integrity in the resultant bonded device stack. Electrical integrity may be tested using a high potential tester. The high potential testing should be conducted after each bonding step to guarantee relatively consistent dielectric strength of the packaging.

Referring again to FIG. 5, next, the method includes aligning power devices and 3D overlay features in the designed order using soldering molds. After all alignments, the method may include soldering components in a single shot to allow more reliability. Next, the method includes bonding (or soldering if the pads have nickel or gold plating) source, gate, and Kelvin pads using wire bonding machine. Next, the method includes assembling gate leads and finishing encapsulation.

Table 2 summarizes nomenclature, reference numerals, and descriptions of the key steps used in the methods described herein to construct the devices described herein, according to some embodiments of the present disclosure.

TABLE 2
Method Steps (see FIG. 5)

| # | Name | Description |
|---|---|---|
| 410 | 1^{st} bonding | Bonding the DC bus bar to the polyimide surface of the baseplate |
| | | (Bonding is hot-pressing here and hereafter) |
| 415 | 1^{st} pre-bonding | Fix the polyimide film in place between the DC+ and DC− bus bars |
| | | by bonding with a mold |
| 420 | 1^{st} aligning | Place and hold everything in place to prepare for full bonding of |
| | | the polyimide film between the DC+ and DC− bus bars |
| 425 | 2^{nd} bonding | Fully bonding the polyimide film in place between the DC+ and |
| | | DC− bus bars |
| 430 | 2^{nd} aligning | Place and hold the AC bus bars in place to prepare for pre-bonding |
| | | of the AC bus bars |
| 435 | 2^{nd} pre-bonding | Fix the AC bus bars to the surface of the baseplate polyimide by |
| | | bonding with a mold |
| 440 | 3^{rd} aligning | Place the 2^{nd} piece of high temperature rubber (145) on top of four |
| | | separate pieces of high temperature rubber (142) for the final |
| | | bonding of four 144 |
| 445 | 4^{th} aligning | Place the pressing tool (145) on top of 145 for preparing the final |
| | | bonding of four 144 |
| 450 | 3^{rd} bonding | Four 144 have been bonded onto the top surface of 105 with |
| | | 115/120/125 and DC− bus bar already bonded in place from earlier |
| | | bonding. |
| 455 | high electric | Put high voltage-bearing probes on top of bonded conductors on |
| | potential testing | 105 and conducted high voltage blocking test to make sure that |
| | | separate conductors have good electrical isolation |
| 460 | 5^{th} aligning | Placing and aligning MOSFET all eight chips on top of |
| | | 115/120/125 and 144 |
| 465 | 6^{th} aligning | Removing the chip-placing fixture and leaving the aligned chips on |
| | | top of 115/120/125 and four 144 |
| 470 | 7^{th} aligning | placing the conductor bridges between 1) the top surfaces of upper |
| | | position half bridge chips and four 144 and 2) the top surfaces of |
| | | lower position half bridge chips and DC− bus bar, using another |
| | | alignment fixture |
| 475 | 8^{th} aligning | Placing and aligning the vertical current terminals into the slots on |
| | | DC+ and DC− bus bars for preparation of soldering them to the |
| | | respective bus bars |
| 480 | soldering | Conductor bridges and current terminals are soldered. |
| 485 | attaching | Attaching gate control pins to the power module |

FIG. 5 illustrates a method 400 for manufacturing the devices described herein, according to some embodiments of the present disclosure. This method 400 includes, among other things, a first bonding 410 of a third dielectric layer 207 to a baseplate 205 to form a first stack, followed by a first pre-bonding 415 of the third dielectric layer 207 to a multi-lobed structure 215 to form a second stack, wherein the first pre-bonding 415 utilizes a mold to hold in place and align the second stack. The method 400 may then continue with a second bonding 425 of the second stack, followed by positioning and aligning 430 at least four single-lobed structures 244 onto the second stack to form a third stack. The method 400 may then continue with a second pre-bonding (435) of the third stack. In some embodiments of the present disclosure, the method 400 may utilize a high temperature rubber for at least one of the first bonding, the first pre-bonding, the second bonding, the second pre-bonding, or a combination thereof. In some embodiments of the present disclosure, a surface of at least one of the baseplate 205, the multi-lobed structure 215, at least one single-lobed structure 244, or a combination thereof is roughened before completing at least one of the first bonding, the first pre-bonding, the second bonding, the second pre-bonding, or a combination thereof.

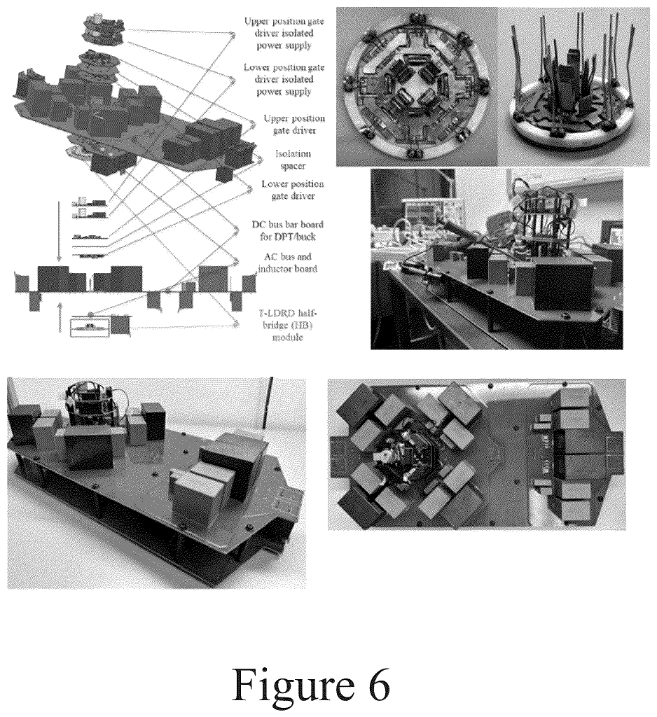

In some embodiments of the present disclosure (see FIG. 6), two types of solder, IND5.7LT and NC-SMQ80 were used. The exemplary SiC MOSFET HB as shown in FIG. 6 was finished per the routine and passed approximately 1.5 kV offline high potential tests. A double pulse testing (DPT)/buck converter test bench is designed and assembled accommodate the footprint of the example module shown in FIG. 6.

The DPT/buck converter test setup as shown in FIG. 6 was designed and fabricated to handle the target ratings of the HB module prototype of approximately 1.2 kV and approximately 400A, and the assembled and encapsulated prototype has passed approximately 1.2 kV high potential tests on all nodes. However, due to the limit capacity of serviceable power sources at the moment of the testing, a downgraded approximately 100V, 10A test was conducted for proof-of-concept.

The test set up was run in buck converters mode during testing. On the primary DC side, the test setup has an effective approximately 97 μF DC link capacitance and 84.4 nF decoupling capacitance across the mounting contacts for the DC terminal leads of the module. Both the DC link capacitors and the decoupling capacitors are arranged symmetrically corresponding to the four pairs of terminal leads of the module to achieve substantially current symmetry. The effective total inductance between the decoupling capacitors and the contacts of the DC board and the module terminal leads is approximately 0.5 nH according to FEA simulation result whose details are not shown here for conciseness. The buck converter has 45 μF output capacitance. A 5Ω resistive load is used to induce as high as approximately 10A load current condition. A Rogowski coil current probe is attached to one of the DC-terminal leads of the module to monitor transient current. The gate drivers for both positions have approximately 1.0Ω output resistance.

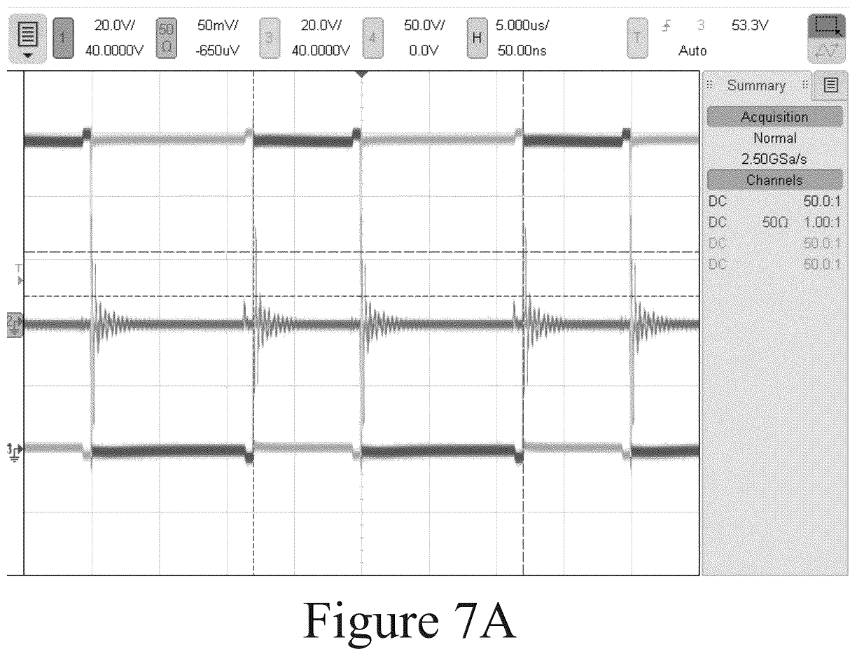

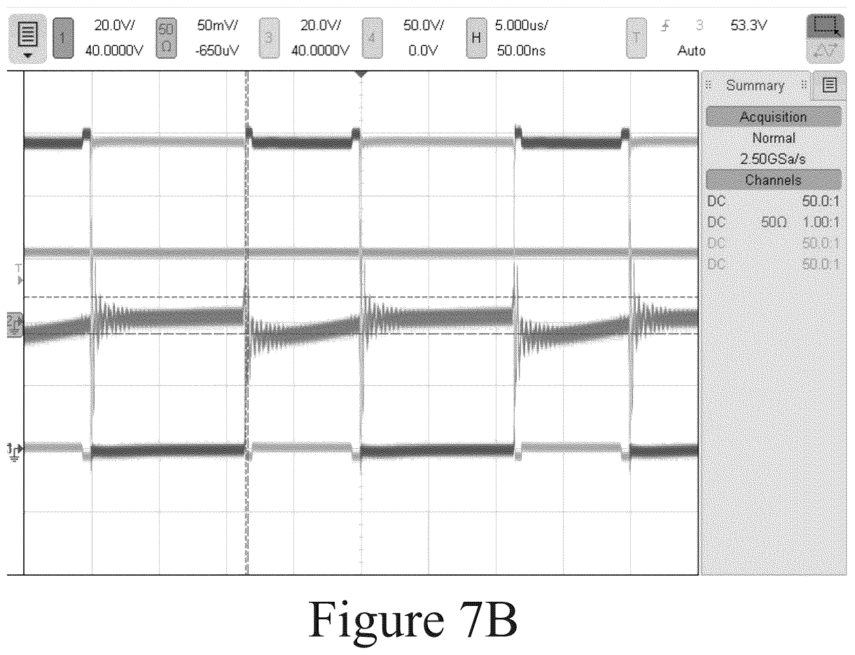

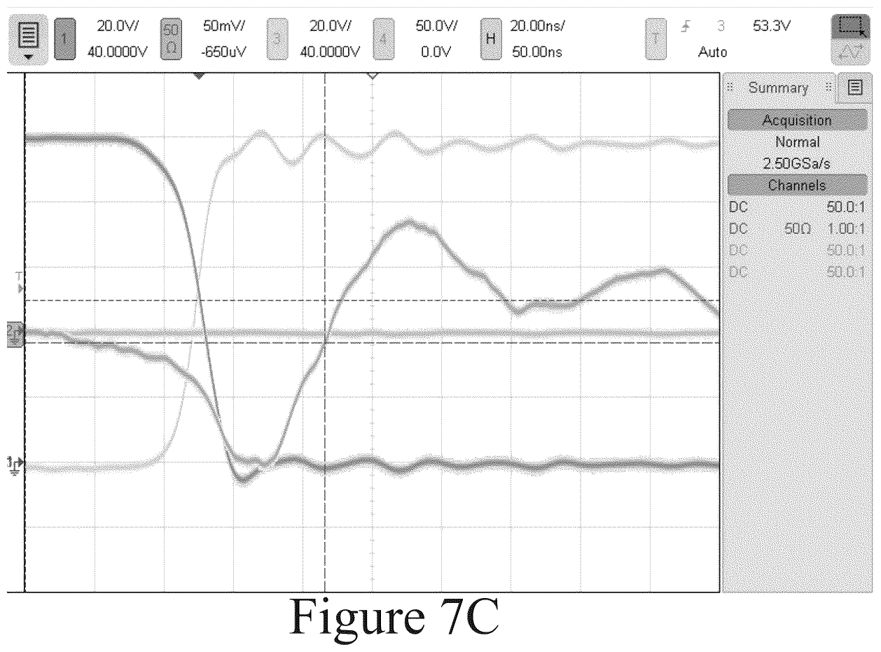

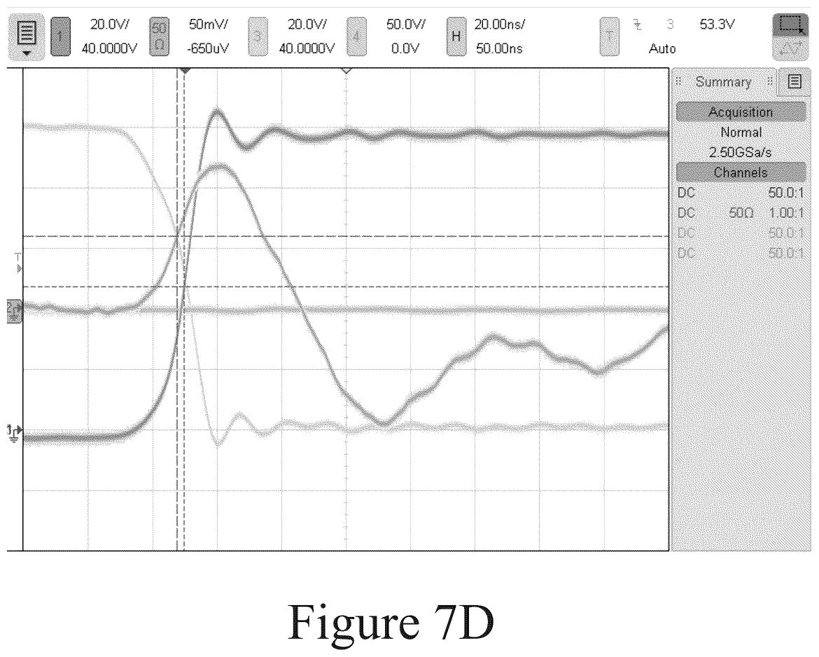

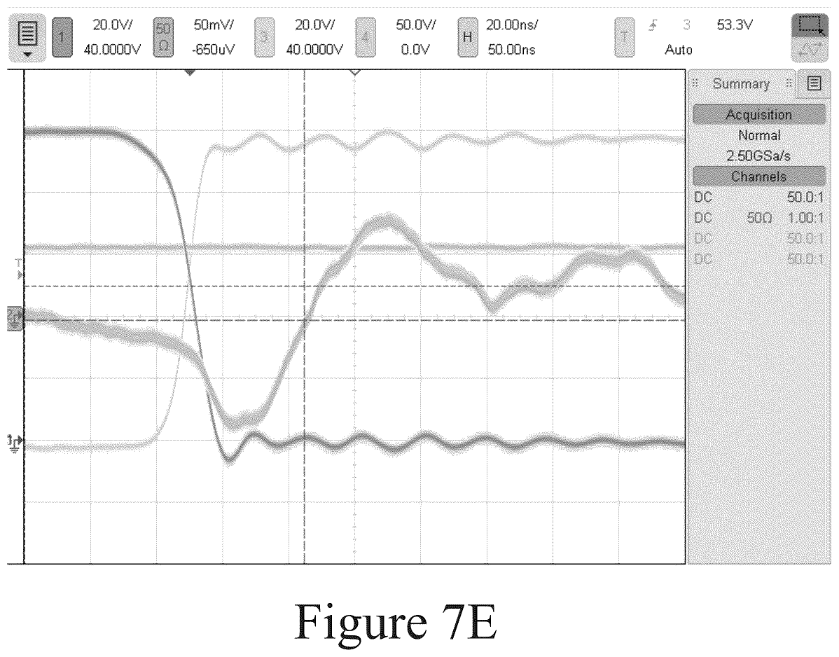

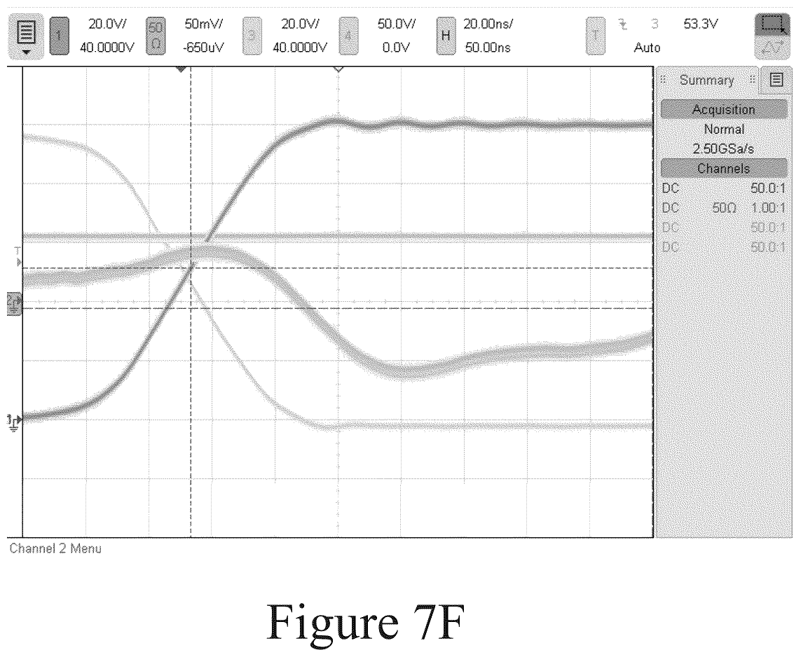

FIGS. 7A-7F illustrate experimental evaluation of the switching transient performance of the exemplary SiC MOSFET HB module, according to some aspects of the present disclosure. Panel (a) shows 50 kHz switching waveform overview, zero load with no output inductor connected, panel (b) shows 50 kHz switching wave-form overview, 10A load current, panel (c) shows high-side switch turn-on transient under zero load with no output inductor connected, panel (d) shows high-side switch turn-off transient under zero load with no output inductor connected, panel (e) shows high-side switch turn-on transient under 10A load current, and panel (f) shows high-side switch turn-off transient under 10A load current. FIGS. 7A-7F provide experimental results under both zero-load condition with no output inductor and approximately 10A load condition. The gate drivers provide maximum voltage slew rate of approximately 10V/ns. Under the voltage slew rate, the run-on and turn-off ringing overshoot is no more than 5% of the total voltage, and the peak-to-peak voltage ringing is less than approximately 8% of the total voltage. These values show little to no noticeable changes between zero load and 10A load conditions. It is evident that low loop inductance is achieved with the test setup.

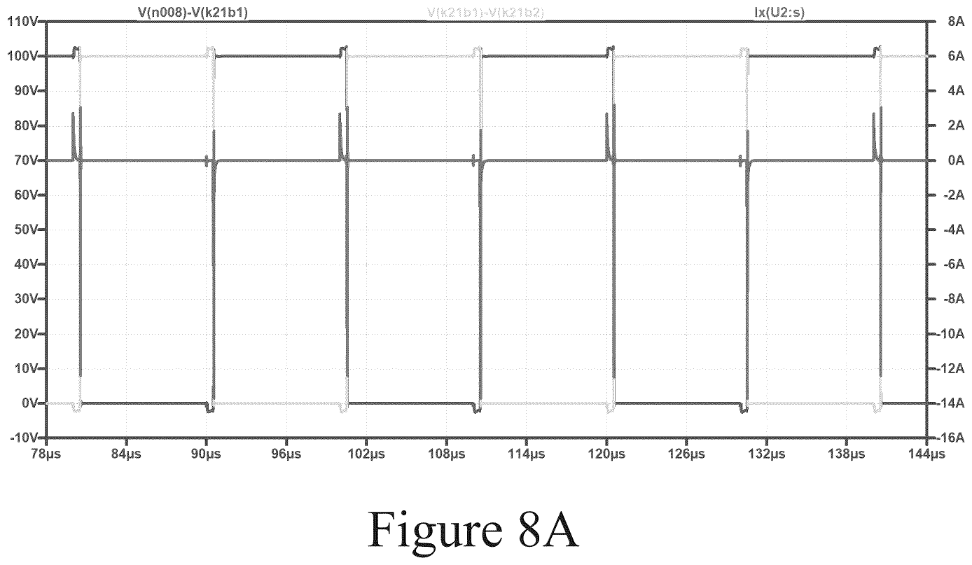

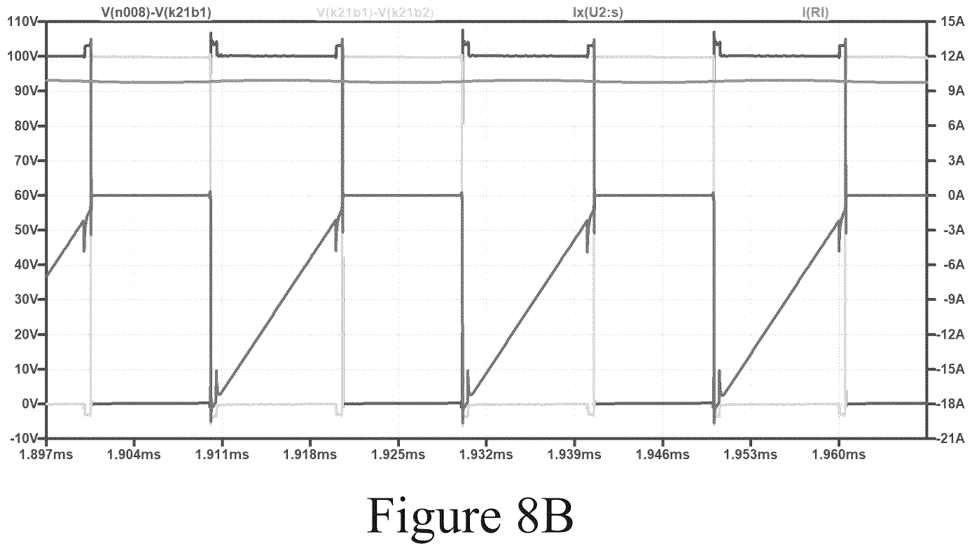

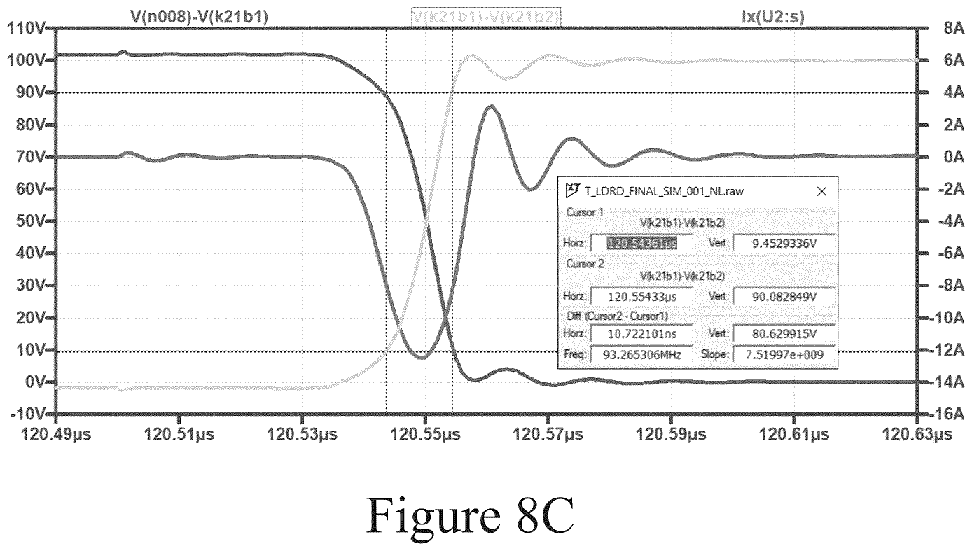

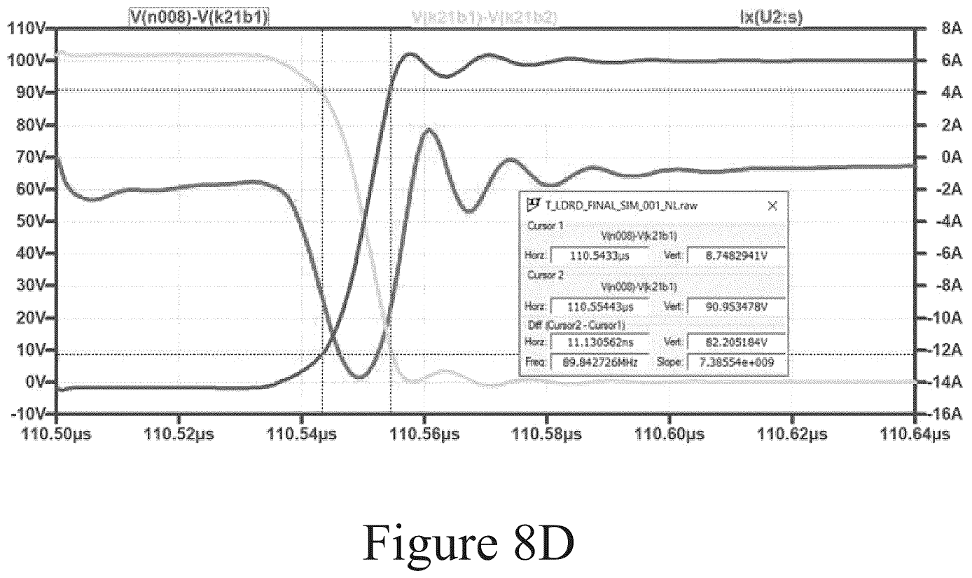

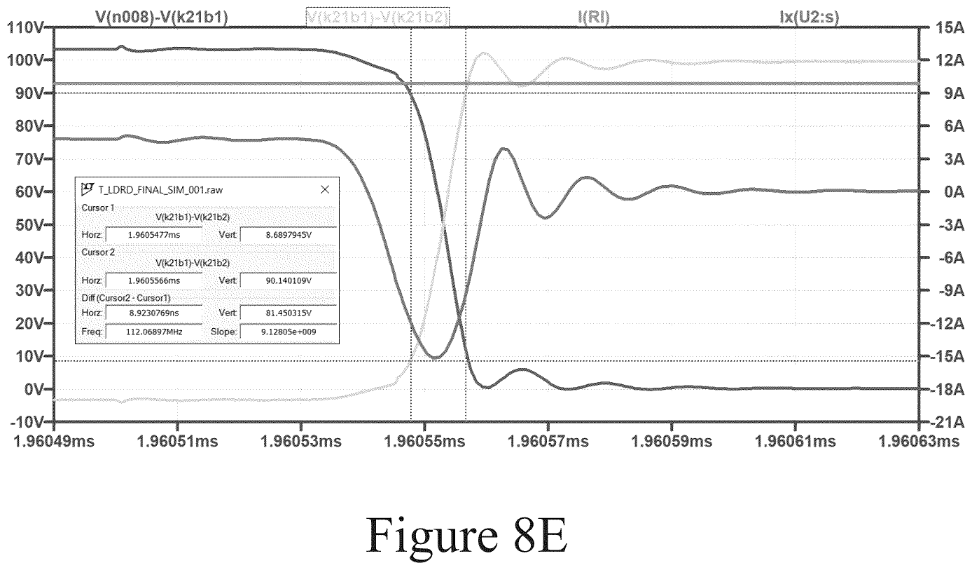

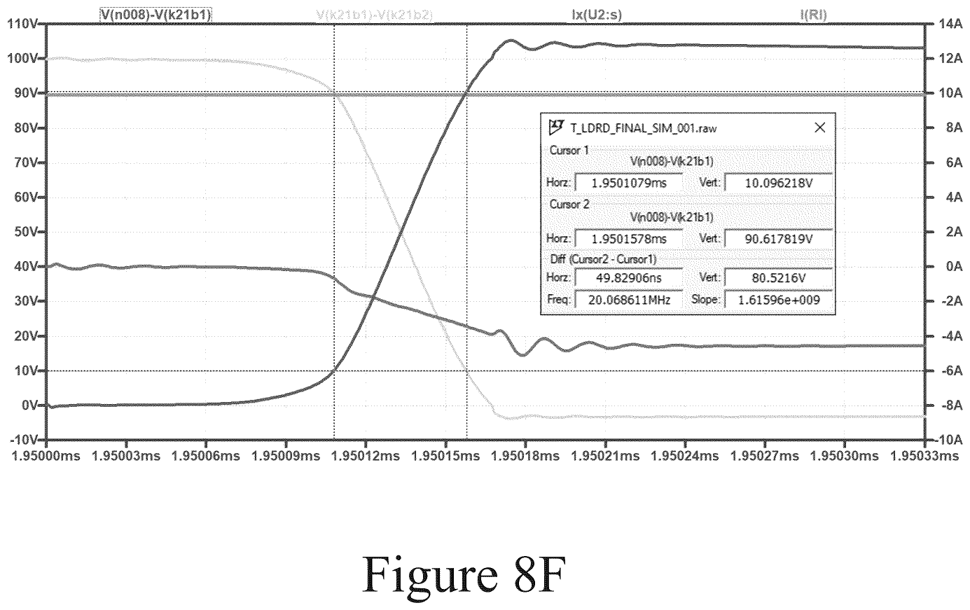

In order to quantitatively verify the sub-nH loop inductance achieved with the HB module prototype, LTspice circuit simulation models with manufacturer SPICE model of the SiC bare die MOSFETs and test bench capacitance and inductance values from real-world measurements or FEA results. Stray inductance between the decoupling capacitors and the SiC devices terminals are adjusted such that the simulated switching transient waveforms match the experimental measurements. FIGS. 8A-8F illustrate the simulation results under the exact settings of the experimental testing. As shown in these figures, the transient waveforms have little to no noticeable difference from the experimental measurements regarding voltage slew rates, overshoot percentage, and peak-to-peak ringing percentage. The stray inductance between the decoupling capacitors and the SiC devices terminals for these simulations are set to be approximately 1.2 nH with even distribution for high-side and low side. As a result, the estimated HB module loop inductance is approximately 0.7 nH which sufficiently matches the FEA results.

The experimental results show the overall power loop stray inductance (including the PCB bus bars and probe wiring) to be less than or equal to approximately 7.5 nH which suggests a better than state-of-the-art module level metrics.

Experimental proof of concept work was directed to manufacturing devices as described above, using the manufacturing methods described above. One manufactured embodiment was a device, specifically a 1.2 kV, 400A symmetrical organic direct-bonded copper (ODBC) SiC metal-oxide-semiconductor field-effect transistor (MOSFET) half bridge (HB) module. As shown herein, the design of this device leverages the properties of the polymer (e.g. polyimide dielectric material (PDM)) in fast prototyping. The resulting 3-dimensional (3D) current path layout has a minimized loop area and a 0.59 nH module-level loop inductance. Derated double-pulse tests (DPT) were conducted to validate the ultra-low current loop inductance. A circuit-module electrothermal co-simulation was conducted to give a brief thermal evaluation at the maximum load condition and demonstrated its potential in boosting power density. The low-cost prototyping steps are also introduced to inspire similar techniques for fast iteration of ODBC-based packaging.

In general, apart from the ductility, the PDM has extremely high specific dielectric strength and reasonable thermal resistance compared to the most popular ceramic materials. PDM's thermal stability is very high up to 500° C., providing considerable fabrication processing headroom, enabling rapid prototyping and manufacturing. Spectroscopy identified two energy absorption peaks in PDM at 9.3 μm and 10.6 μm, two wavelengths commonly utilized to enable CO₂ laser cutting, suggesting PDM may be easily customized into desirable shapes and features using a common laser in large batches.

Various experiments were performed on the PDM to study its properties and its interactions with different materials. The following features regarding the PDM used in the prototype devices described herein were determined.

The PDM bonded to metal surfaces when subjected to high temperature and pressure at the same time. with a pressure in a range between 200 psia and 400 psia (nominally about 300 psia) at a temperature between 300° C. and 400° C. yielded satisfactory and reliable bonding, when applied for a period of time between 5 seconds and 10 minutes (nominally about one minute).

The PDM did not bond to most nonmetal materials, including but not limited to metal oxidation layers, various plastics, rubbers, resins, polytetrafluoroethylene, and silicon dioxide. In addition, the surface roughness of the object being bonded to is important for achieving reliable bonding. A roughness average (Ra) value between 10 μm and 20 μm is resulted in superior bonding. Too smooth a surface resulted in weak bonding, while too rough a surface sometimes resulted in puncturing the PDM. An oxidation layer normally resulted in bonding failure. Further, it was determined that particles on the PDM surface may compromise the isolation strength and surface smoothness. Maintaining these guidelines resulted in a bonding process that could be repeated an indefinite number of times without compromising the PDM. Notably, longer hot pressing durations had no observable negative impact on reliability and bonding quality.

These properties of the PDM used in the various dielectric layers described herein and utilized in the prototype devices described herein offered a high degree of flexibility in rapid manufacturing of devices, mainly by allowing deforming of already-bonded components into desirable geometries and allowing multi-step masking and bonding to form desirable patterns for the various dielectric layers.

FIGS. 2 and 3 illustrate a device design inspired by the PDM properties, according to some embodiments of the present disclosure. The device essentially combines four distinct devices, wired electrically in parallel (see FIG. 1). There is an overall symmetry of each group of components used to construct each of the four devices around the y-axis, enabled at least partially, by the use of dielectric materials like the PDM.

In the proposed device design, the multi-lobed structure 215 (i.e. DC+ node) and midpoint busbars (i.e., single-lobed structures 244) are used as the primary thermal conduction path. The heat loss goes through these busbars and the main PDM layer (the third dielectric layer 207) to reach the copper baseplate 205. The alignment structure 260 (i.e., DC− busbar) has a compact and symmetrical footprint and is bonded to the top surface of the planar tabs 270 (i.e., DC+ busbar) with a secondary layer of PDM (the first dielectric layer 265) to achieve close lamination and symmetrical current paths, and at the same time provide moderate DC capacitance. A pair of circular copper bridges, for high-side and low-side dies respectively (the first conductive bridge 280 and second conductive bridge 290, respectively), are also laminated and bonded by a second dielectric layer 285 of PDM, connecting the high-side source to the midpoint and the low-side source to DC− from each die to its adjacent die position (electronic element 110, single-lobed structures 244, and the alignment structure 260, respectively). The unique DC bus bar stacking and laminated bridges enable compact and symmetrical current paths through the device.

Manufacturing steps for making the devices described herein are illustrated in FIG. 5 with steps summarized above in Table 2. Four primary tools were used. A consumer-grade computer numerical control (CNC) milling machine capable of working on copper at 0.1-mm precision, for copper features. A hot press that can be assembled from consumer-grade linear stages, stepper motors, a heating plate that can heat to a temperature between 350° C. and 500° C., thermal couples and temperature control, pressure sensors, and Python programming for controlling temperature and pressure, for bonding PDM and copper. These items combine to create a system capable of low-cost, fast, flexible manufacturing. Alternative approaches with the same functionality can also be adopted. A 3D printer that can print materials with temperature not less than the hot press temperature and sufficient rigidity to withstand at least 300-psi pressure without major uneven deformation. A consumer-grade laser cutter may be employed to cut dielectric materials or any other types of film material cutters that can cut through, for example, a 50 μm thick polyimide material sheet.

### EXAMPLES

Example 1. A device comprising: a plurality of electrically conductive layers; a plurality of dielectric layers; and at least two recesses positioned in at least one electrically conductive layer, each recess configured to receive an electronic element, wherein: the electrically conductive layers are positioned parallel to a reference plane (the xz-plane), the dielectric layers are positioned parallel to the reference plane, and the electrically conductive layers and the dielectric layers are positioned to form a stack that is aligned symmetrically in the direction of a reference axis (the y-axis) that is perpendicular to the reference plane and in a substantially circular arrangement around the reference axis (the y-axis).

Example 2. The device of Example 1, wherein the device is configured to transfer electricity to the electronic elements and transfer heat away from electronic elements positioned in recesses.

Example 3. The device of Example 1 and/or Example 2, wherein the electrically conductive layers are constructed using a first material having an electrical conductivity between 1×10⁶ S/m and 100×10⁶ S/m.

Example 4. The device of any one of Examples 1-3, wherein the first material comprises a metal.

Example 5. The device of any one of Examples 1-4, wherein the metal comprises at least one of copper, aluminum, silver, gold, nickel, steel, molybdenum, or a combination thereof.

Example 6. The device of any one of Examples 1-5, wherein the dielectric layers are constructed using a second material having an electrical conductivity between 1×10⁻¹⁷ S/m and 1×10⁻¹⁰ S/m.

Example 7. The device of any one of Examples 1-6, wherein the second material comprises a polymer, a resin, or a combination thereof.

Example 8. The device of any one of Examples 1-7, wherein the polymer or resin has a dielectric strength between 4 kV and 6.5 kV.

Example 9. The device of any one of Examples 1-8, wherein the polymer or resin has a thermal conductivity between 0.2 W/[m·K] and 0.7 W/[m·K].

Example 10. The device of any one of Examples 1-9, wherein the polymer or resin comprises at least one of a polyimide, a polyetherimide (PEI), a polyetheretherketone (PEEK), polytetrafluoroethylene (PTFE), polyethylene terephthalate (PET), polyethylene naphthalate (PEN), an epoxy resin, or a combination thereof.

Example 11. The device of any one of Examples 1-10, wherein the polymer or resin is capable of being cut using a CO₂ laser cutter.

Example 12. The device of any one of Examples 1-11, wherein: the electrically conductive layers comprise a multi-lobed structure comprising: a central hub having a center positioned at the reference axis, at least four lobes, each physically connected to the central hub and positioned radially around the reference axis, at least four spaces, each space positioned between two adjacent lobes and positioned around the reference axis, and at least one lobe comprises at least one of the at least two recesses.

Example 13. The device of any one of Examples 1-12, wherein the multi-lobed structure is configured to function as a DC+ contact (i.e., DC+ node).

Example 14. The device of any one of Examples 1-13, wherein each lobe has a polygonal shape.

Example 15. The device of any one of Examples 1-14, wherein: the electrically conductive layers further comprise at least four single-lobed structures, each single-lobed structure comprises a lobe and a tab protruding from the lobe at an angle perpendicular to the lobe and aligned perpendicular to the reference axis, and at least one lobe comprises at least one of the at least two recesses.

Example 16. The device of any one of Examples 1-15, wherein each single-lobed structure is configured to function as an AC contact (i.e., AC node).

Example 17. The device of any one of Examples 1-16, wherein each lobe of a single-lobed structure is positioned within one of the spaces positioned between adjacent lobes of the multi-lobed structure.

Example 18. The device of any one of Examples 1-17, wherein the multi-lobed structure and the lobe of each single-lobed structure are positioned within a single plane that is parallel to the reference plane.

Example 19. The device of any one of Examples 1-18, wherein: the electrically conductive components further comprise an alignment structure comprising at least four notches and at least four slots, each notch is configured to receive and align the tab of one of the single-lobed structures, and each slot is positioned between two notches.

Example 20. The device of any one of Examples 1-19, wherein the alignment structure is configured to function as a DC− bus bar.

Example 21. The device of any one of Examples 1-20, further comprising: a first dielectric layer, wherein: the first dielectric layer has a shape substantially similar to the alignment structure and comprises at least four notches and at least four slots, the first dielectric layer is positioned between the alignment structure and the single-lobed structures, and each notch of the first dielectric layer is configured to receive the tab of a single-lobed structure.

Example 22. The device of any one of Examples 1-21, further comprising: at least four planar tabs positioned perpendicularly to the reference plane, wherein: each planar tab passes through a slot of the alignment structure and a slot of the first dielectric layer.

Example 23. The device of any one of Examples 1-22, wherein the planar tabs are configured to function as DC+ bus bars.

Example 24. The device of any one of Examples 1-23, further comprising: at least four flanged planar tabs positioned perpendicularly to the reference plane, wherein: each flanged planar tab is positioned parallel to and adjacent to one of the planar tabs.

Example 25. The device of any one of Examples 1-24, wherein there is a gap between the flanged planar tab and the planar tab.

Example 26. The device of any one of Examples 1-25, wherein the flanged planar tabs are configured to function as DC− bus bars.

Example 27. The device of any one of Examples 1-26, wherein: the electrically conductive layers further comprise a first conductive bridge comprising at least four notches, each configured to receive a tab of a single-lobed structure, and the first conductive bridge is electrically connected to the alignment structure.

Example 28. The device of any one of Examples 1-27, wherein the first conductive bridge is configured to function as an electrical contact between the electronic elements and the alignment structure.

Example 29. The device of any one of Examples 1-28, further comprising: a second dielectric layer, wherein: the second dielectric layer has a shape substantially similar to the first conductive bridge and comprises at least four notches, the first conductive bridge is positioned between the second dielectric layer and the alignment structure, and each notch of the second dielectric layer is configured to receive and align the tab of one of the single-lobed structures.

Example 30. The device of any one of Examples 1-29, wherein: the electrically conductive layers further comprise a second conductive bridge, and the second dielectric layer is positioned between the second conductive bridge and the first conductive bridge.

Example 31. The device of any one of Examples 1-30, wherein the second conductive bridge is configured to function as an electrical contact between the electronic elements and the single-lobed structures.

Example 32. The device of any one of Examples 1-31, further comprising: a third dielectric layer, and the electrically conductive layers further comprise a baseplate, wherein: the third dielectric layer is positioned between the multi-lobed structure and the baseplate.

Example 33. The device of any one of Examples 1-32, wherein the device is a half-bridge power module.

Example 34. The device of any one of Examples 1-33, wherein the plurality of electronic elements comprises metal-oxide-semiconductor field-effect transistors (MOSFETs).

Example 35. The device of any one of Examples 1-34, wherein the multi-lobed structure comprises between 4 and 20 lobes, or between 4 and 10 lobes.

Example 36. The device of any one of Examples 1-35, wherein the multi-lobed structure has four lobes.

Example 37. The device of any one of Examples 1-36, wherein each lobe of the multi-lobed structure comprises between 1 and 10 recesses, or between 1 and 4 recesses.

Example 38. The device of any one of Examples 1-37, wherein each lobe of the multi-lobed structure has a single recess.

Example 39. The device of any one of Examples 1-38, comprising between 4 and 20 single-lobed structures, or between 4 and 10 single-lobed structures.

Example 40. The device of any one of Examples 1-39, wherein the device has four single-lobed structures.

Example 41. The device of any one of Examples 1-40, wherein each lobe of each single-lobed structure comprises between 1 and 10 recesses, or between 1 and 4 recesses.

Example 42. The device of any one of Examples 1-41, wherein each lobe of each single-lobed structure has a single recess.

Example 43. A method for manufacturing a device, the method comprising, a first bonding (410) of a third dielectric layer (207) to a baseplate (205) to form a first stack.

Example 44. The method of Example 43, further comprising a first pre-bonding (415) of the third dielectric layer (207) to a multi-lobed structure (215) to form a second stack, wherein the first pre-bonding (415) utilizes a mold to hold in place and align the second stack.

Example 45. The method of Example 43 and/or Example 44, further comprising a second bonding (425) of the second stack.

Example 46. The method of any one of Examples 44-45, further comprising positioning and aligning (430) at least four single-lobed structures (244) onto the second stack to form a third stack.

Example 47. The method of any one of Examples 44-46, further comprising a second pre-bonding (435) of the third stack.

Example 48. The method of any one of Examples 44-47, further comprising the use of a high temperature rubber for at least one of the first bonding, the first pre-bonding, the second bonding, the second pre-bonding, or a combination thereof.

Example 49. The method of any one of Examples 44-48, wherein a surface of at least one of the baseplate, the multi-lobed structure, at least one single-lobed structure, or a combination thereof is roughened before completing at least one of the first bonding, the first pre-bonding, the second bonding, the second pre-bonding, or a combination thereof.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

The foregoing discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

What is claimed is:

1. A device comprising:
a plurality of electrically conductive layers;
a plurality of dielectric layers; and
at least two recesses positioned in at least one electrically conductive layer, each recess configured to receive an electronic element, wherein:
the electrically conductive layers are positioned parallel to a reference plane,
the dielectric layers are positioned parallel to the reference plane, and
the electrically conductive layers and the dielectric layers are positioned to form a stack that is aligned symmetrically in the direction of a reference axis (the y-axis) that is perpendicular to the reference plane and in a substantially circular arrangement around the reference axis.

2. The device of claim 1, wherein the device is configured to transfer electricity to the electronic elements and transfer heat away from electronic elements positioned in recesses.

3. The device of claim 1, wherein:
the electrically conductive layers comprise a multi-lobed structure comprising:
a central hub having a center positioned at the reference axis,
at least four lobes, each physically connected to the central hub and positioned radially around the reference axis,
at least four spaces, each space positioned between two adjacent lobes and positioned around the reference axis, and
at least one lobe comprises at least one of the at least two recesses.

4. The device of claim 3, wherein:
the electrically conductive layers further comprise at least four single-lobed structures,
each single-lobed structure comprises a lobe and a tab protruding from the lobe at an angle perpendicular to the lobe and aligned perpendicular to the reference axis, and
at least one lobe comprises at least one of the at least two recesses.

5. The device of claim 4, wherein each lobe of a single-lobed structure is positioned within one of the spaces positioned between adjacent lobes of the multi-lobed structure.

6. The device of claim 4, wherein the multi-lobed structure and the lobe of each single-lobed structure are positioned within a single plane that is parallel to the reference plane.

7. The device of claim 4, wherein:
the electrically conductive components further comprise an alignment structure comprising at least four notches and at least four slots,
each notch is configured to receive and align the tab of one of the single-lobed structures, and
each slot is positioned between two notches.

8. The device of claim 7, further comprising:
a first dielectric layer, wherein:
the first dielectric layer has a shape substantially similar to the alignment structure and comprises at least four notches and at least four slots,
the first dielectric layer is positioned between the alignment structure and the single-lobed structures, and
each notch of the first dielectric layer is configured to receive the tab of a single-lobed structure.

9. The device of claim 8, further comprising:
at least four planar tabs positioned perpendicularly to the reference plane, wherein:
each planar tab passes through a slot of the alignment structure and a slot of the first dielectric layer.

10. The device of claim 9, further comprising:
at least four flanged planar tabs positioned perpendicularly to the reference plane, wherein:
each flanged planar tab is positioned parallel to and adjacent to one of the planar tabs.

11. The device of claim 10, wherein there is a gap between the flanged planar tab and the planar tab.

12. The device of claim 10, wherein:
the electrically conductive layers further comprise a first conductive bridge comprising at least four notches, each configured to receive a tab of a single-lobed structure, and
the first conductive bridge is electrically connected to the alignment structure.

13. The device of claim 12, further comprising:
a second dielectric layer, wherein:
the second dielectric layer has a shape substantially similar to the first conductive bridge and comprises at least four notches,
the first conductive bridge is positioned between the second dielectric layer and the alignment structure, and
each notch of the second dielectric layer is configured to receive and align the tab of one of the single-lobed structures.

14. The device of claim 13, wherein:
the electrically conductive layers further comprise a second conductive bridge, and
the second dielectric layer is positioned between the second conductive bridge and the first conductive bridge.

15. A method for manufacturing a device, the method comprising, a first bonding of a third dielectric layer to a baseplate to form a first stack.
